(19) United States
(12) Patent Application Publication
(10) Pub. No.: US 2025/0105146 A1
(43) Pub. Date: Mar. 27, 2025

(54) HIGH-DENSITY THREE-DIMENSIONAL MEMORY DEVICE WITH INTERCONNECTION OF LOW RESISTANCE AND MANUFACTURING METHOD THEREOF

(71) Applicant: CHENGDU PBM TECHNOLOGY LTD., Sichuan, Chengdu (CN)

(72) Inventors: Jack Zezhong PENG, Chengdu (CN); Ke WANG, Chengdu (CN)

(21) Appl. No.: 18/255,811

(22) PCT Filed: Dec. 30, 2022
(86) PCT No.: PCT/CN2022/144167

§ 371 Date: Jun. 2, 2023

(30) Foreign Application Priority Data
May 13, 2022 (CN) 202210516577.2

(51) Int. Cl. H01L 23/522; H01L 21/768; H01L 23/528; H10D 8/00; H10D 8/60

(52) U.S. Cl. CPC H01L 23/5228; H01L 21/76831; H01L 23/5283; H10D 8/411; H10D 8/60

(57) ABSTRACT

A high-density three-dimensional memory device with interconnection of low resistance and a manufacturing method thereof are provided. The device includes an underlying circuit part, and a base structure disposed on the underlying circuit part. The base structure includes first conductive medium layers and insulating medium layers which are alternately stacked on each other from bottom to top. The base structure has dendritic interdigitated structure, the dendritic interdigitated structure is composed of two dendritic structures. The dendritic structure includes a trunk and branches connected to and perpendicular to the trunk. A preset number of memory holes are formed in a curved division trench between the branches and an external structure. A vertical electrode perpendicular to the bottom surface of the base structure is disposed in the memory hole, a storage medium required for a preset memory type is disposed between the vertical electrode and an inner wall of the memory hole.

### CROSS-REFERENCES TO RELATED APPLICATIONS

This is a national stage application of International Patent Application No. PCT/CN2022/144167, filed on Dec. 30, 2022, which claims the benefit and priority of Chinese Patent Application No. 202210516577.2, filed with the China National Intellectual Property Administration on May 13, 2022, the disclosures of which are hereby incorporated by reference herein in their entirety as part of the present disclosure.

### TECHNICAL FIELD

The present disclosure belongs to integrated circuit technologies, and in particular relates to semiconductor memory technologies.

### BACKGROUND

Three-dimensional memory in the prior art usually needs to include characteristics of state changing and feature of diodes at the same time, where the former is used as the carrier of data storage, and the latter is configured to control data reading and writing characteristics. The diode characteristics can be achieved by semiconductor PN diodes, Schottky diodes, etc. Directly applying one of the essential components of a diode, such as a low-resistance P-type (or N-type) semiconductor or Schottky metal, as horizontal interconnection lines in each stacking layer of a three-dimensional memory has the advantages of simple process and low manufacturing cost, the disadvantage of which is that the resistivity of the horizontal interconnection lines is relatively high, especially when the length of a horizontal wire is usually hundreds of, thousands of microns, or orders of magnitude greater, so that the interconnection line formed by the low-resistance semiconductor (e.g., highly doped polycrystalline silicon) has a great influence on reading and writing of the memory.

Process steps are disclosed in Chinese patent application 202110233574.3 “a manufacturing method of a high-density three-dimensional programmable memory”. In Chinese patent application 202110233574.3, when the high-density storage is achieved, as the length of the horizontal wire is extremely long (up to hundreds to thousands of microns) while the width is short (down to tens of nanometers), the horizontal conductor has a high series resistance, which is likely to lead to a failure of the reading and writing function of the memory device unit, as shown in FIG. 1.

The application of a metal silicide on the polycrystalline silicon may improve the circuit interconnection by reducing resistance of the interconnection line and contact resistance. However, in the previously disclosed 3D multilayer stacking memory device with low-resistance semiconductors as interconnection lines in each stacking layer, it is impossible to apply a low-resistance silicide layer onto the low-resistance semiconductor layer of the horizontal wire. The reason is that such an arrangement may lead to a redundant connection and contact between the low-resistance silicide and the storage medium, causing the storage medium in contact with the silicide also be programmed. Taking the anti-fuse storage medium as an example, the result is that, after the breakdown of the storage medium, a functional PN junction diode that should have been formed by a horizontal P-type (or N-type) semiconductor layer and a vertical N-type (or P-type) semiconductor is short-circuited by the redundant connection formed by the silicide on top of the horizontal P-type (or N-type) semiconductor layer and the vertical N-type (or P-type) semiconductor, leading to the failure of reading/writing performance characteristics of the memory cell device.

Therefore, in order to ensure the reading and writing performance of the memory without sacrificing the manufacturing cost, it is necessary to better improve a three-dimensional architecture of multi-layer stacking devices.

### SUMMARY

The technical problem to be solved by the present disclosure is to provide a new three-dimensional multi-layer memory with the characteristics of low resistance.

The present disclosure further provides a manufacturing method of a high-density three-dimensional memory with low resistance, which has the advantages of simplified process and low interconnection resistance.

The technical solution employed by the present disclosure for solving the technical problem is that a high-density three-dimensional memory with low-resistance connection includes an underlying circuit part, and a base structure disposed on the underlying circuit part, where the base structure includes first conductive medium layers and insulating medium layers which are alternately stacked on each other from bottom to top.

The base structure has dendritic interdigitated structure. The dendritic interdigitated structure is composed of two dendritic structures, and a curved division trench is formed between the two dendritic structures.

The dendritic structure includes at least one trunk and branches connected to and perpendicular to the trunk, and at least three branches are disposed on at least one side of both sides of the trunk.

A preset number of memory holes are formed in the curved division trench. The upper opening of each memory hole is located on a plane where the top face of the base structure is located, and the lower opening of each memory hole is located on a plane where the bottom face of the base structure is located. The memory holes are independent of one another, and the adjacent memory holes are isolated from each other by an insulating material.

A vertical electrode perpendicular to the bottom face of the base structure is disposed in the memory hole, and a storage medium required for a preset memory device is provided between the vertical electrode and an inner wall of the memory hole.

Further, at least two memory holes are formed in each middle division region, and the middle division region is a part of the curved division trench that is parallel to the orientation of the branches. The branches are symmetrically distributed on both sides of the trunk. The first conductive medium, the storage medium and the electrode are made of materials required to constitute a semiconductor memory.

Further, the first conductive medium is made of a low-resistance semiconductor material or Schottky metal. The preset memory is a PN junction type semiconductor memory, a Schottky diode memory, or a retentive medium memory.

The retentive medium memory is a resistance change memory, a magnetic phase change memory, a phase change memory, or a ferroelectric memory.

The width of the trunk is greater than that of the branch.

A manufacturing method of a high-density three-dimensional memory device with interconnection of low resistance provided by the present disclosure includes the following steps:
1) step of forming a base structure: a preset number of first conductive medium layers and insulating medium layers are disposed in a manner that the first conductive medium layers and the insulating medium layers are alternately stacked on each other to form the base structure;
2) step of forming a dendritic structure on the base structure:
a curved division trench penetrating through the base structure from a top layer to a bottom layer is formed to divide the base structure into two dendritic structures, where each dendritic structure body includes at least one trunk and at least three branches connected to and perpendicular to the trunk; and
3) step of forming a pillar-shaped memory body: a sequence of pillar-shaped memory bodies is disposed in the curved division trench, where adjacent pillar-shaped memory bodies are isolated from each other by an insulating material, and the pillar-shaped memory body includes a vertical electrode perpendicular to the bottom face of the base structure, and a storage medium surrounding the electrode.

Step 3) includes the following steps:
(3.1) filling the curved division trench with an insulating medium;
(3.2) forming memory holes from the bottom layer to the top layer of the base structure through the insulating medium in the curved division trench, where the axis of the memory holes is vertical to the bottom face of the base structure, to form a memory hole sequence; and
(3.3) according to a preset memory structure, arranging a buffer layer and the storage medium on the inner wall of the memory hole layer by layer, and then filling an electrode material to form a vertical electrode.

Alternatively, step 3) includes the following steps:
(3.a) according to a preset memory structure, arranging a buffer layer and the storage medium on the inner wall of the curved division trench layer by layer, and filling an electrode material;
(3.b) forming isolation holes from the bottom layer to the top layer of the base structure in the curved division trench, where the axis of the isolation holes is perpendicular to the bottom face of the base structure, and a sequence of memory bodies separated by the isolation holes is formed; and
(3.c) filling the isolation holes with an insulating material.

Further, in step (3.2), the memory hole sequence disposed along the curved division trench is arranged as a memory hole array.

In accordance with the present disclosure, the series resistance of horizontal wires is reduced while the high-density storage is achieved. The resistance of the slender horizontal wires in an original device structure is reduced by inserting a distributed trunk structure. The series resistance of the device at the corresponding position can be reduced by several times by using the trunk part which has a larger width in the dendritic structure and has negligible resistance compared with the slender branch, thus reducing the voltage drop during reading and writing and ensuring the reading and writing performance of the device. The manufacturing method provided by the present disclosure is low in process cost and high in yield.

### BRIEF DESCRIPTION OF THE DRAWINGS

FIG. 1 is a schematic diagram of a prototype structure known in the art.

FIG. 2 is a stereoscopic diagram of a base structure.

FIG. 3 is a top view of a prototype structure in accordance with the present disclosure.

FIG. 4 is a sectional view of a prototype structure in accordance with the present disclosure from the front.

FIG. 5 is a schematic diagram of a prototype structure with a curved division trench in a top direction.

FIG. 6 is a schematic diagram of a highlighting trunk part of a prototype structure with a curved division trench.

FIG. 7 is a sectional view of a prototype structure with a curved division trench in an A-A′ direction.

FIG. 8 is a schematic diagram of steps of filling an insulating material in accordance with an embodiment 1.

FIG. 9 is a sectional view of steps shown in FIG. 8 in an A-A′ direction of a prototype structure.

FIG. 10 is a schematic diagram of steps of forming memory cells in accordance with an embodiment 1.

FIG. 11 is a schematic diagram of steps of providing a pillar-shaped memory body in accordance with an embodiment 1.

FIG. 12 is a partial enlarged view of FIG. 11.

FIG. 13 is a schematic diagram in accordance with an embodiment 2.

FIG. 14 is a schematic diagram in accordance with an embodiment 3.

FIG. 15 is a schematic diagram of a middle division region.

FIG. 16 is a schematic diagram in accordance with an embodiment 4.

FIG. 17 is a schematic diagram in accordance with an embodiment 5.

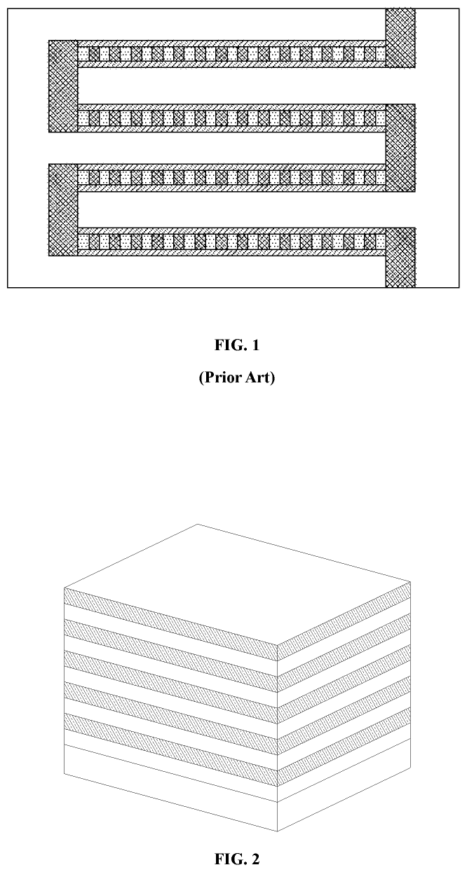

### DETAILED DESCRIPTION OF THE EMBODIMENTS

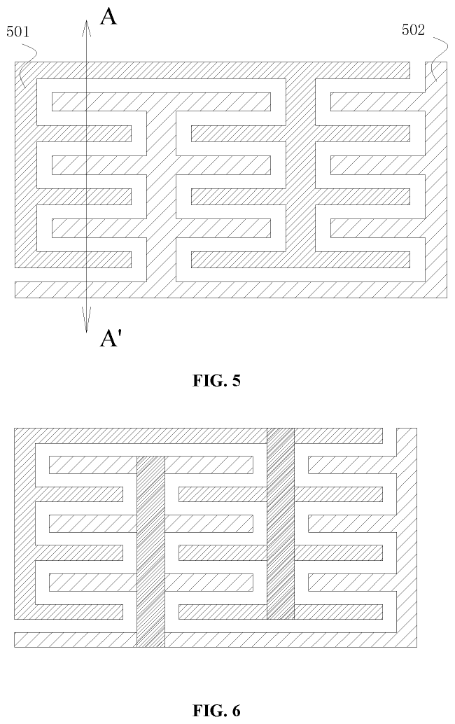

In an ideal state, the widths of the top and the bottom of a trench or hole formed by an etching process are consistent. However, in the actual process, the top and the bottom are difficult to be consistent. Referring to FIG. 5, the sectional view of a prototype structure in an A-A′ direction is shown according to the actual situation, where the division trench is trapezoid with a wide upper part and a narrow lower part. For the sake of simplicity, the top view does not show such a trapezoidal structure and is hereby illustrated.

The various materials involved in the present disclosure may be made of one of the following four items:

(1) A vertical electrode is made of a N+ semiconductor, a buffer layer is made of a lightly doped N-type semiconductor, a storage medium is made of an insulating medium, and a first conductive medium layer is made of a P+ semiconductor.

(2) A vertical electrode is made of a N+ semiconductor, a buffer layer is made of a lightly doped N-type semiconductor, a storage medium is made of an insulating medium, and a first conductive medium layer is made of P-type Schottky metal (e.g., Ag, Au, Pt, Ni).

(3) A vertical electrode is made of a P+ semiconductor, a buffer layer is made of a lightly doped P-type semiconductor, a storage medium is made of an insulating medium, and a first conductive medium layer is made of a N+ semiconductor or a semiconductor.

(4) A vertical electrode is made of a P+ semiconductor, a buffer layer is made of a lightly doped P-type semiconductor, a storage medium is made of an insulating medium, and a first conductive medium layer is made of N-type Schottky metal (e.g., Ti, indium zinc oxide).

### Embodiment 1

This embodiment is a first embodiment of a manufacturing method, including the following steps:

A1. Abase structure is formed on an underlying circuit 43:

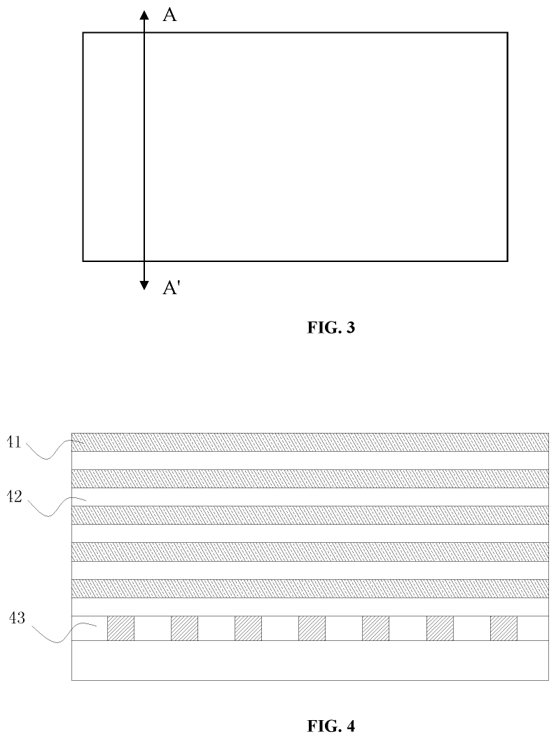

A preset number of first conductive medium layers and a preset number of insulating medium layers are disposed in a manner that the first conductive medium layers 41 and the insulating medium layers 42 are alternately stacked on each other so as to form the base structure. FIG. 2 is a stereoscopic diagram, FIG. 3 is a top view, and FIG. 4 is a sectional view in an A-A′ direction.

A2. The base structure is trenched:

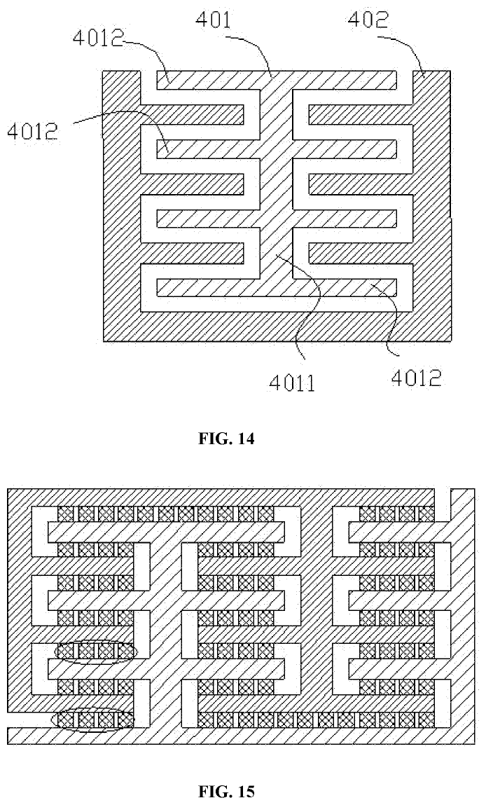

Referring to FIG. 5 and FIG. 6, the base structure is divided by a curved division trench into two dendritic structures, a first dendritic structure 401 and a second dendritic structure 402, respectively. The case of two main trunks is shown in FIG. 5. The main trunk is a trunk with branches on both left and right sides. The trunk with branches on only one side is called a secondary trunk. Referring to the case shown in FIG. 14, one main trunk and two secondary trunks are included.

Preferably, the width of the trunk is greater than that of the branch. For example, the width of branch may be in the order of 0.1 micron or lower according to the process and storage density requirements, while the width of trunk may be set in the order of 1 micron or higher according to the requirements of device performance. Considering the trunk and the branch from the viewpoint of the wire resistance, the width is negatively correlated with the resistance value in the case of equal thickness, so the width of trunk is preferably larger than the width of branch.

From a top view, the dendritic structure includes at least one trunk and branches connected to and perpendicular to the trunk, and at least three branches are arranged on at least one side of both sides of the trunk. Two main trunks are shown in FIG. 6 in densified shaded regions. In FIG. 5, different shadows are merely configured to distinguish two independent parts that are divided by the curved division trench rather than representing material differences.

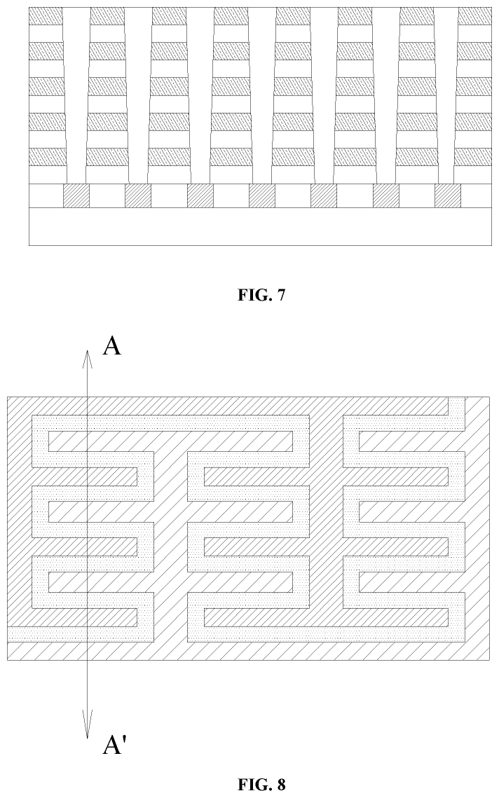

FIG. 7 is a sectional view of FIG. 5 in an A-A′ direction.

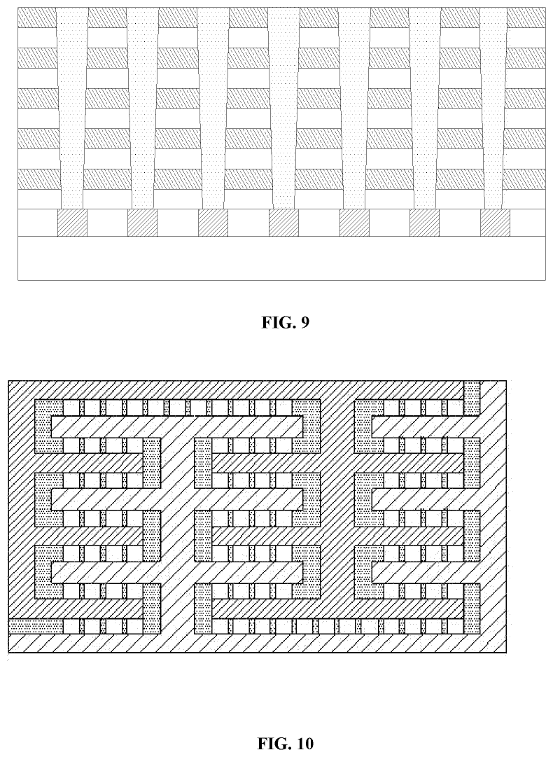

A3. An insulating medium is filled in the division trench, referring to FIG. 8 and FIG. 9.

A4. Memory holes are etched along the division trench filled with the insulating medium by using an under-mask etching process so as to expose the base structure from the etched memory holes. In the present disclosure, the insulating medium between two adjacent memory holes may employ a small thickness, or, a spacing distance between the two adjacent memory holes may be made relatively small depending on current mature etching techniques (e.g., 10 nm and below), and remains not less than the breakdown thickness of the insulating medium (e.g., the breakdown thickness of a silicon dioxide layer is 0.5 nm to 5 nm), referring to FIG. 10.

A5. Referring to FIG. 11, a storage medium and a vertical electrode are deposited in the memory hole to form a pillar-shaped memory body 901.

The vertical electrodes should be electrically connected to the underlying circuit, via bottom regions penetrating through the memory holes by etching process before the vertical electrodes being disposed, or the bottom regions of the memory holes being broken down by high voltage after the vertical electrodes are disposed.

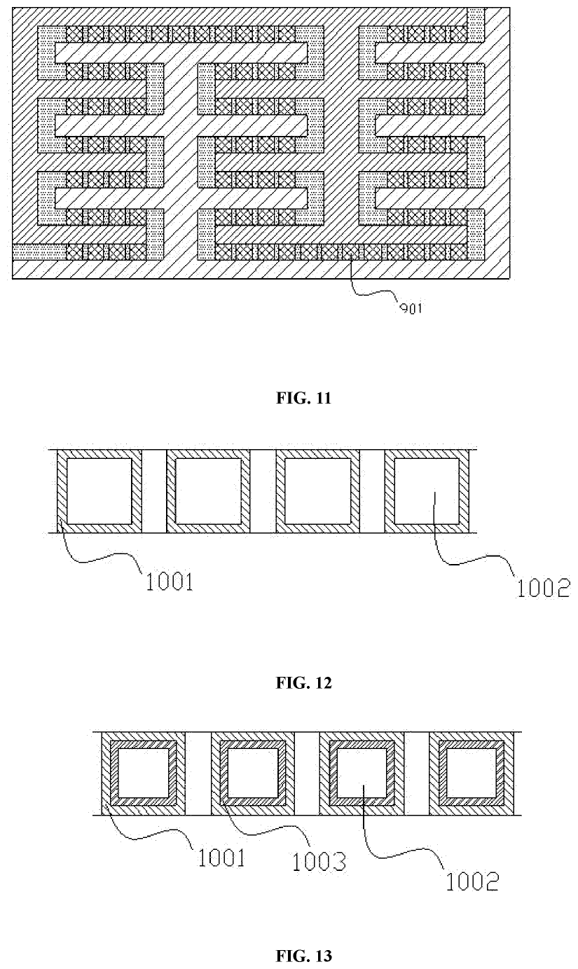

A partial part of FIG. 11 is enlarged in FIG. 12, where a layer of storage medium 1001 and a vertical electrode 1002 are disposed in the memory hole, and the storage medium is an insulating medium. FIG. 12 is an enlarged view of four pillar-shaped memory bodies 901.

### Embodiment 2 (with a Buffer Layer)

Referring to FIG. 13, the difference between this embodiment and the embodiment 1 is that a buffer layer 1003 is further disposed on the surface of the storage medium layer.

### Embodiment 3

This embodiment is a high-density three-dimensional memory device with interconnection of low resistance, including an underlying circuit part, and a base structure disposed on the underlying circuit part. The base structure comprises first conductive medium layers and insulating medium layers which are alternately stacked on each other from bottom to top.

Referring to FIG. 14, the base structure has dendritic interdigitated structure. The dendritic interdigitated structure shown in FIG. 14 includes a first dendritic structure 401 and a second dendritic structure 402, where a curved division trench is formed between the two dendritic structures, and the base structure is divided into two dendritic structures by the curved division trench.

Referring to FIG. 14, from a top view, the first dendritic structure includes a main trunk 4011 and branches 4012 connected to and perpendicular to the main trunk, and at least three branches are disposed on each side of both sides of the main trunk. The second dendritic structure 402 includes two secondary trunks, and branches are disposed on one side of the secondary trunk.

The case of one main trunk is described in this embodiment. In the previous embodiment 1, the case of two main trunks is shown in FIG. 5.

Multiple memory holes are formed in the curved division trench, where the number of the memory cells is preset and is determined according to the design capacity of the memory. An upper opening of each memory hole is located on a plane where the top face of the base structure is located, and a lower opening of each memory hole is located on a plane where the bottom face of the base structure is located. The memory holes are independent of one another, and the adjacent memory holes are isolated from each other by an insulating material. The base structure with the curved trench groove filled with the insulating material is regarded as a whole, where the memory holes penetrate through the whole from top to bottom, straight to the underlying circuit from the top face.

A vertical electrode perpendicular to the bottom face of the base structure is disposed in each memory hole, and a storage medium required for a preset memory type is provided between the vertical electrode and an inner wall of the memory hole.

Apart, parallel to the orientation of the branch, of the curved division trench is called a middle division region, referring to the part in an elliptical frame in FIG. 15, at least two memory holes are formed in each middle division region.

In this embodiment, the branches are symmetrically distributed on both sides of the trunk. The case of asymmetry is not excluded in the present disclosure.

The first conductive medium, the storage medium and the electrode in this embodiment are made of materials required to constitute a semiconductor memory.

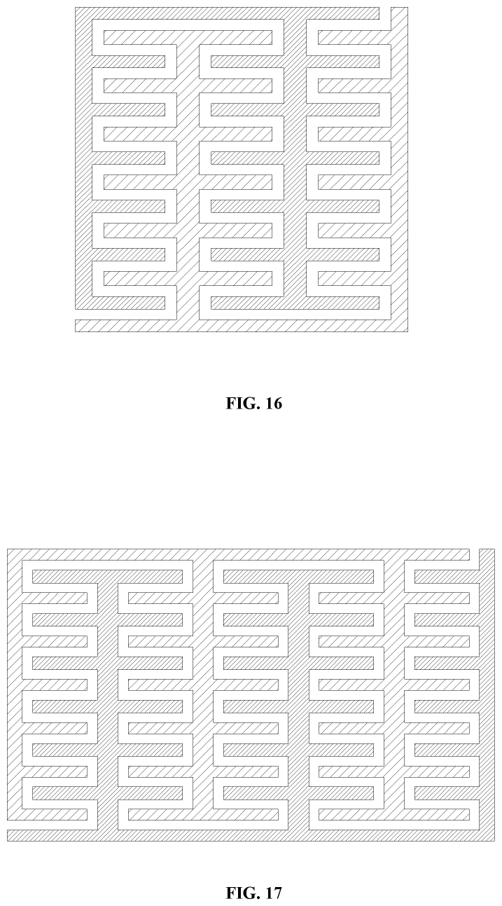

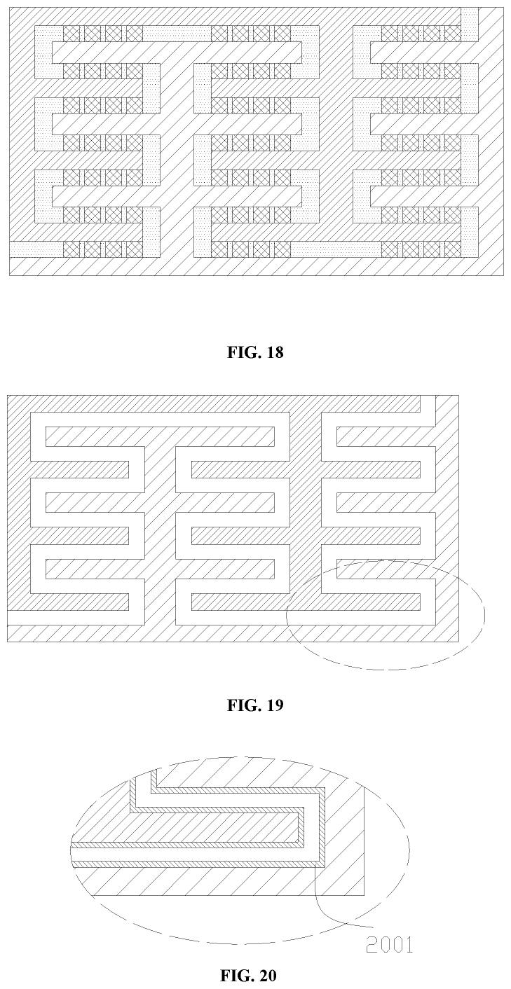

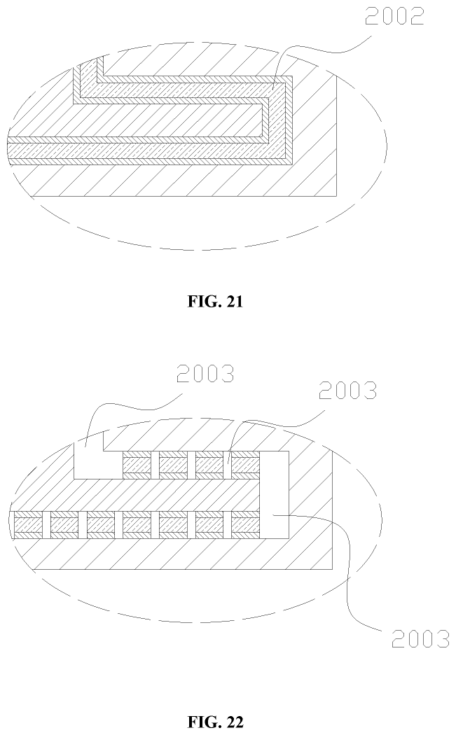

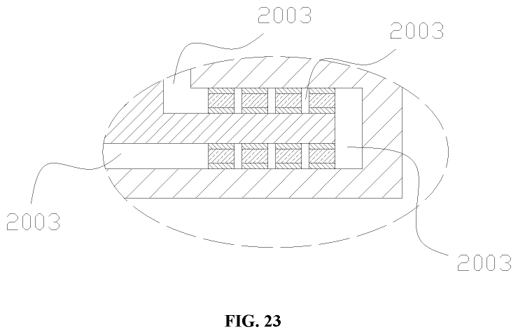

The case of more branches is shown in an embodiment 4 shown in FIG. 16 and an embodiment 5 shown in FIG. 17.

What is claimed is:

1. A high-density three-dimensional memory device with interconnection of low resistance, comprising an underlying circuit part, and a base structure disposed on the underlying circuit part, wherein the base structure comprises first conductive medium layers and insulating medium layers which are alternately stacked on each other from bottom to top;
the base structure has dendritic interdigitated structure, wherein the dendritic interdigitated structure is composed of two dendritic structures, and a curved division trench is formed between the two dendritic structures;
each dendritic structure comprises at least one trunk and branches connected to and perpendicular to the trunk, and at least three branches are disposed on at least one side of both sides of the trunk;
a preset number of memory holes are formed in the curved division trench, an upper opening of each memory hole is located on a plane where the top face of the base structure is located, a lower opening of each memory hole is located on a plane where the bottom face of the base structure is located, the memory holes are independent of one another, and the adjacent memory holes are isolated from each other by an insulating material;
a vertical electrode perpendicular to the bottom face of the base structure is disposed in the memory hole, and a storage medium required for a preset memory device is provided between the vertical electrode and an inner wall of the memory hole.

2. The high-density three-dimensional memory device with interconnection of low resistance according to claim 1, wherein at least two memory holes are formed in each middle division region, and the middle division region is a part, parallel to the pointing of the branch, of the curved division trench.

3. The high-density three-dimensional memory device with interconnection of low resistance according to claim 1, wherein the first conductive medium, the storage medium and the electrode are made of materials required to constitute a semiconductor memory.

4. The high-density three-dimensional memory device with interconnection of low resistance according to claim 1, wherein the first conductive medium is made of a semiconductor material.

5. The high-density three-dimensional memory device with interconnection of low resistance according to claim 1, wherein the preset memory is a PN junction type semiconductor memory, a Schottky diode memory or a medium memory;
the medium memory is a resistance change memory, a magnetic phase change memory, a phase change memory, or a ferroelectric memory.

6. A manufacturing method of a high-density three-dimensional memory device with interconnection of low resistance, comprising the following steps:
1) step of forming a base structure: providing a preset number of first conductive medium layers and insulating medium layers in a manner that the first conductive medium layers and the insulating medium layers are alternately stacked on each other to form the base structure;
2) step of forming a dendritic structure on the base structure: forming a curved division trench penetrating through the base structure from a top layer to a bottom layer to divide the base structure into two dendritic structures, wherein each dendritic structure body comprises at least one trunk and at least three branches connected to and perpendicular to the trunk; and
3) step of forming a pillar-shaped memory body: providing a sequence of pillar-shaped memory bodies in the curved division trench, wherein adjacent pillar-shaped memory bodies are isolated from each other by an insulating material, and the pillar-shaped memory body comprises a vertical electrode perpendicular to the bottom face of the base structure, and a storage medium surrounding the electrode.

7. The manufacturing method of a high-density three-dimensional memory device with interconnection of low resistance according to claim 6, wherein step 3) comprises the following steps:
(3.1) filling the curved division trench with an insulating medium;
(3.2) forming memory holes extending from the bottom layer to the top layer of the base structure on the insulating medium in the curved division trench, wherein the axis of the memory holes is vertical to the bottom face of the base structure, and a memory hole sequence is formed; and
(3.3) according to a preset memory structure, arranging a buffer layer and a storage medium in the memory hole, and then filling an electrode material to form a vertical electrode.

8. The manufacturing method of a high-density three-dimensional memory device with interconnection of low resistance according to claim 6, wherein step 3) comprises the following steps:
(3.a) according to a preset memory structure, arranging a buffer layer and a storage medium in the curved division trench, and then filling an electrode material;
(3.b) forming isolation holes extending from the bottom layer to the top layer of the base structure in the curved division trench, wherein the axis of the isolation holes is perpendicular to the bottom face of the base structure, and a memory body sequence separated by the isolation holes is formed; and
(3.c) filling the isolation holes with an insulating material.

9. The manufacturing method of a high-density three-dimensional memory device with interconnection of low resistance according to claim 6, wherein the width of the trunk is greater than that of the branch.
